(19) United States
(12) Patent Application Publication
(10) Pub. No.: US 2004/0144970 A1
(43) Pub. Date: Jul. 29, 2004

(54) Nanowires

(76) Inventors: Dunwei Wang, Stanford, CA (US); Hongjie Dai, Sunnyvale, CA (US)

Correspondence Address: Crawford Maunu PLLC, Suite 390, 1270 Northland Drive, St. Paul, MN, 55120, US

(21) Appl. No.: 10/680,571

(22) Filed: Oct. 7, 2003

Related U.S. Application Data
(60) Provisional application No. 60/416,568, filed on Oct. 7, 2002.

(51) Int. Cl. H01L 29/06

(52) U.S. Cl. 257/17

(57) ABSTRACT

Nanowires are formed using an approach that facilitates efficient and economical growth thereof. According to an example embodiment of the present invention, a gas including a semiconducting material (e.g., single-crystal germanium) is introduced to a conductive metal particle (e.g., gold) on an insulating substrate to grow a nanowire therefrom. In one implementation, an alloy is formed from the semiconducting material and the conductive metal particle, with the nanowire being grown from the alloy. In another implementation, a co-flow of hydrogen is used with the gas including the semiconducting material to facilitate the growth of the nanowire.

### RELATED PATENT DOCUMENTS

This patent document relates to U.S. Provisional Patent Application Serial No. 60/416,568, entitled “Germanium Nanowires” and filed on Oct. 7, 2002, to which priority is claimed under 35 U.S.C. §120 for common subject matter.

### FIELD OF THE INVENTION

The present invention relates generally to semiconductor devices and more particularly to devices and approaches involving the formation of nanowires and germanium-based nanowires.

### BACKGROUND

Recent technological advances in the electronics industry have permitted dramatic increases in circuit density and complexity, and equally dramatic decreases in circuit sizes. For example, single-die microprocessors are presently being manufactured with many millions of transistors, operating at speeds of hundreds of millions of instructions per second and being packaged in relatively small, air-cooled semiconductor device packages. The improvements in such devices have led to a dramatic increase in their use in a variety of applications. As the use of these devices has become more prevalent, the demand for compact circuits has also increased. In this regard, the demand for nanometer-scale circuits and interconnects is ever increasing. Similarly, as medical, mechanical and other fields continue to explore the use of nanometer-scale devices, the demand for structural, electrical and chemical elements having nanometer-scale dimensions is also increasing.

Chemically derived nanowire materials such as germanium-based materials and others have attracted much attention due to their interesting geometry, properties and potential applications. Various methods have been developed for synthesizing semiconducting nanowires, including laser ablation physical vapor deposition under high temperatures and solvothermal growth under high pressures and moderate temperatures. For example, laser ablation nanowire growth has been carried out at about 820° C., vapor transport nanowire growth has been carried out at about 900-1100° C. using solvothermal nanowire growth methods (at about 300-400° C., 100 atm). However, these methods have proven challenging for reliable, economical implementation.

The above-mentioned and other difficulties have presented challenges to the implementation of electronics devices and nanowires in a variety of applications.

### SUMMARY OF THE INVENTION

The present invention is directed to nanowires such as those based on alloys including germanium and/or other materials, and the fabrication thereof. The present invention is exemplified in a number of implementations and applications, some of which are summarized below.

According to an example embodiment of the present invention, nanowires are manufactured using vapor deposition. Seed particles are formed on a material-based support structure, such as a silicon oxide insulative substrate. A semiconductor-containing substance, such as a gas (e.g., vapor) with semiconducting material (e.g., germanium) therein, is introduced to the seed particles while the material-based support structure is at an elevated temperature, and nanowires are grown from the seed particles.

In a more particular example embodiment of the present invention, germanium nanowires are grown using CVD in a CVD chamber (e.g., a 1-inch furnace reactor). Au nanocrystals (˜20 μm in diameter) are deposited uniformly on a surface of a SiO₂ substrate from a colloidal solution and form seed particles. A germanium-containing gas (GeH₄ at 10% in He) is flowed across the SiO₂ substrate at a gas flow rate of about a 20 sccm (standard cubic centimeter). About 500 sccm of H₂ co-flow is also flowed across the substrate, with a total gas pressure in the chamber of about 1 atm and for about 15 min. With this approach, a relatively simple chemical vapor deposition approach is implemented for synthesizing high purity single-crystalline Ge nanowires at low temperatures. The growth condition is mild (e.g., relatively low temperature and pressure) for single-crystal nanowire synthesis, and is implemented using efficient GeH₄ feedstock and low eutectic temperature for Ge and Au nanocluster seeds.

The above summary of the present invention is not intended to describe each illustrated embodiment or every implementation of the present invention. The figures and detailed description that follow more particularly exemplify these embodiments.

### BRIEF DESCRIPTION OF THE DRAWINGS

The invention may be more completely understood in consideration of the detailed description of various embodiments of the invention that follows in connection with the accompanying drawings, in which:

FIG. 1(a) is a SEM image of Ge nanowires synthesized using CVD, according to an example embodiment of the present invention;

FIG. 1(b) is a TEM image of Ge nanowires synthesized using CVD, according to another example embodiment of the present invention;

FIG. 2(a) is a high resolution TEM image of a Ge nanowire, according to another example embodiment of the present invention;

FIG. 2(b) shows a TEM image of another Ge nanowire, according to another example embodiment of the present invention;

FIG. 3(a) shows a TEM image showing the end of a Ge nanowire connected to a SiO₂ substrate, according to another example embodiment of the present invention;

FIG. 3(b) shows a. TEM image of another end of the GE nanowire shown in FIG. 3(a);

FIG. 3(c) shows a binary phase diagram for Ge—Au, which can be implemented in connection with another example embodiment of the present invention;

FIG. 3(d) shows a schematic drawing depicting the VLS growth process, according to another example embodiment of the present invention; and

FIGS. 4(a)-(d) show the growth of Ge nanowires on SiO₂/Si involving the patterning of Au particles into squared regions of a substrate, according to another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

The present invention is believed to be applicable to a variety of different types of devices, and the invention has been found to be particularly suited for the manufacture and implementation of germanium nanowires for a variety of circuits. While the present invention is not necessarily limited to such applications, various aspects of the invention may be appreciated through a discussion of various examples using this context.

According to an example embodiment of the present invention, nanowires are grown using a vapor deposition process, such as chemical vapor deposition (CVD). The vapor deposition approach may, for instance, include approaches similar to those used for carbon nanotube growth. With this approach, single-crystal germanium nanowires are formed using vapor deposition with a germanium-containing gas (e.g., GeH₄) at an elevated temperature (e.g., about 275° C.) with seed particles. The seed particles may include, for example, gold (Au) nanocrystals, transition metal particles, other highly-conductive metal particles, metal oxides and/or conductive metal particles having a eutectic phase in alignment with germanium.

In connection with an example embodiment of the present invention, germanium has been discovered to be a useful for producing nanowires having a band gap of about 0.6 eV and exhibiting high carrier mobility. In one implementation, high quality Ge nanowires are synthesized using CVD at about 275° C. and atmospheric pressure. This approach has been discovered to be useful for single-crystal nanowire synthesis via mild growth conditions. Efficient Ge feedstock from GeH₄ and the low eutectic temperature of Ge—Au nanocluster are implemented for vapor-liquid-solid (VLS) growth of Ge nanowire at the low temperature. In a further implementation, a CVD approach is used for patterned growth of Ge nanowires, yielding nanowires from well-defined patterned sites on surfaces.

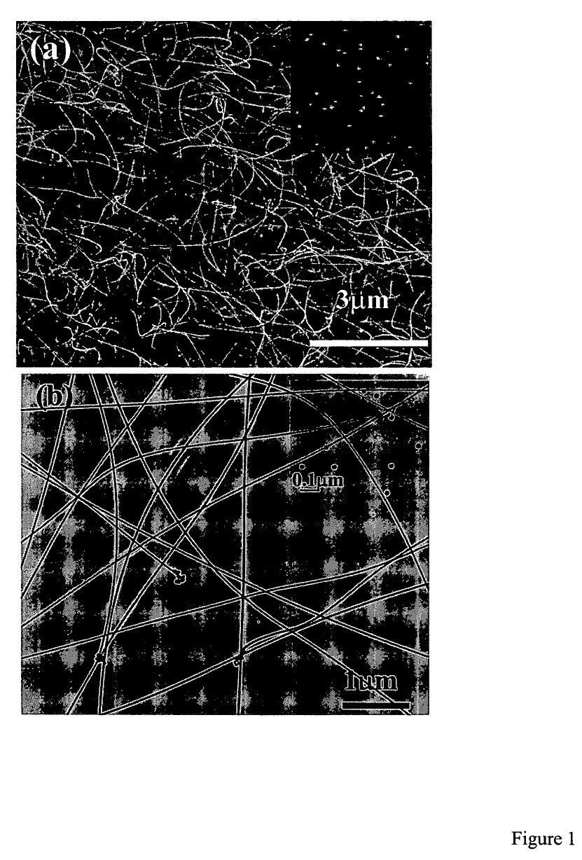

In one example embodiment, CVD growth is carried out at 275° C. under a 20 sccm (standard cubic centimeter) flow of GeH₄ (10% in He) and a 500 sccm of H₂ co-flow in a 1-inch furnace reactor (total gas pressure 1 atm) for 15 min. A SiO₂/Si substrate including preformed Au nanocrystals (˜20 nm in diameter) deposited uniformly on the surface thereof from a colloidal solution is used for growing nanowires. FIG. 1(a) shows an atomic force microscopy (AFM) image of the Au particles on a substrate, recorded before CVD, which may be used in connection with this example embodiment. After CVD, characterization by scanning electron microscopy (SEM) shows high yield growth of nanowire materials on the substrate. The inset of FIG. 1(a) shows an AFM image of Au nanoclusters on the substrate. The nanowires grown are up to tens of microns in length and exhibit high abundance and purity without any appreciable amount of particulate byproducts.

In one implementation, transmission electron microscopy (TEM) is used to characterize the high order structures of CVD grown nanowires. Nanowire synthesis is carried out directly on TEM grids containing thin (˜10 nm) SiO₂ films that are transparent to electron beams. Au nanoparticles are first deposited on a SiO₂ film (FIG. 1b inset), followed by CVD synthesis and TEM imaging without any further processing of the sample (e.g., sonicating nanowires off substrates in a solution). FIG. 1(b) shows a low magnification TEM image in which nanowires with lengths greater than about 10 μm are grown on SiO₂-film (shown with a light background). Using this approach, as shown by the clean SiO₂ background and absence of large particulates, the CVD growth conditions produce pure nanowire materials with little byproducts.

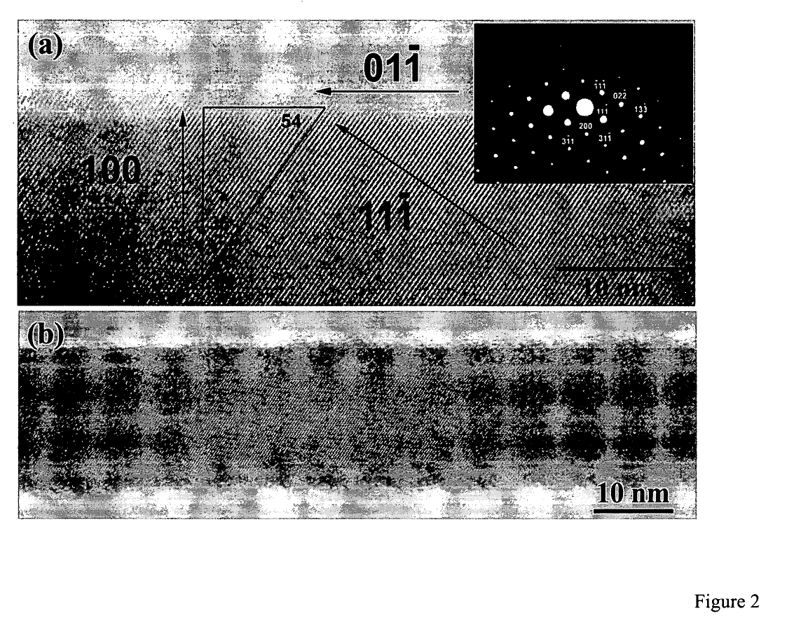

FIG. 2(a) shows a high magnification image of the crystal structure of a Ge nanowire grown in connection with another example embodiment of the present invention. High resolution TEM reveals high quality single-crystalline Ge nanowires grown by CVD. In this implementation, the convergent electron beam diffraction pattern (FIG. 2a inset) for the nanowire is identified to be along the [011] diffraction zone axis. The lattice fringes parallel to the viewing direction in the TEM correspond to the {111} planes (at 54° to the wire axis) of Ge. The spacing between adjacent planes is 3.27 Å, yielding a lattice constant of a=3.27 Å×3=5.66 Å, in excellent agreement with the known diamond crystal structure of Ge. The same lattice constant is derived from the diffraction pattern by using the Bragg formula. The wire axis is identified to be [01\overline{1}] based on the [011] zone-axis and analysis of the lattice structure (FIG. 2a). The Ge nanowires are single-crystalline over most of their lengths (e.g. greater than about 10 μm).

In one implementation, imaging contrast variations along the length of the nanowire are shown in FIG. 1b, which is related to slight rotations of the crystal planes in the nanowire due to van der Waals fixation forces of the substrate (i.e., slight mechanical twisting of the wire). Careful examinations reveal that many of the as-grown wires in fact do not show such variation along the wire axis for more than about 5 μm. For ˜10 wires investigated by high resolution TEM, all of them exhibit a [01\overline{1}] growth direction, as also shown by way of example in FIG. 2b.

In another implementation, a majority of Ge nanowires grown by CVD exhibit growth axes along the <110> crystal direction. In another implementation, in terms of the size of the nanowires, the nanowires are manufactured having an average diameter of about 23 nm, close to the average diameter of the Au colloids from which they are grown.

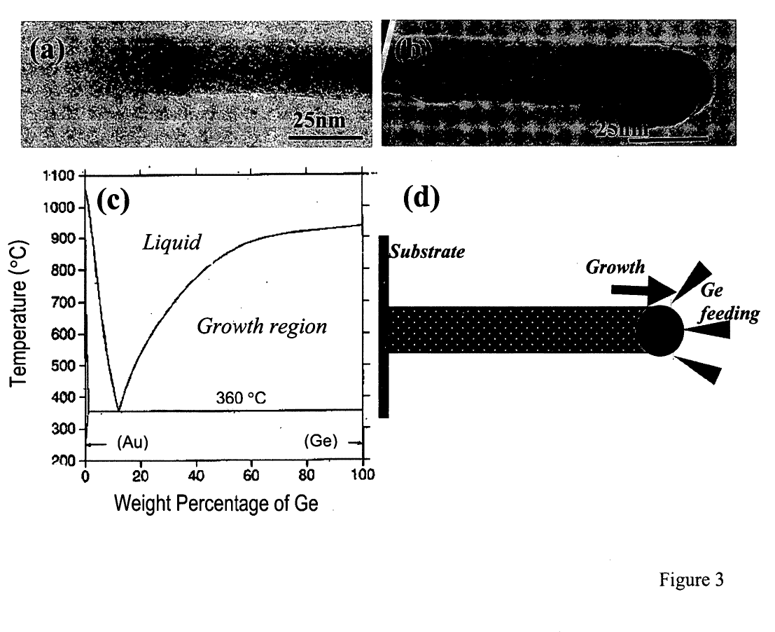

In another implementation, nanowires are synthesized directly on TEM grids in a manner that allows examination of the ends of nanowires in their as-grown states. FIGS. 3a and 3b show TEM images recorded for two ends of a typical nanowire manufactured in connection with another example embodiment. One end of the nanowire is tipped with an Au nanoparticle, and the other end is connected to a SiO₂ substrate from which it is grown (FIG. 3b). In one implementation, the growth of Ge nanowires in our CVD is via an Au particle seeded vapor-liquid-solid (VLS) mechanism, similar to that observed for Ge wires synthesized by laser ablation and vapor transport methods.

The general VLS mechanism involves Ge vapor dissolving in a Au cluster to form alloy at an initial stage, and under continuous Ge feeding, the alloy evolves into a liquid state, and further increases in Ge concentration leading to supersaturation, precipitation and axial growth of a nanowire. A phase diagram for this approach is shown in FIG. 3c and discussed further below. The Au cluster is lifted off from the original position on the substrate, extending as the wire lengthens while the other end of the wire remain connected to the substrate, as shown in FIG. 3d. In one implementation, a growth approach used for an in-situ growth experiment in the TEM involves vaporizing solid Ge to feed Au nanoparticles. For general information involving germanium growth and for specific information regarding approached to germanium growth that may be implemented in connection with this or other example embodiments herein, reference may be made to Y. Wu, P. Yang, J. Am. Chem. Soc. 2001, 123, 3165, and P. Yang, Y. Wu, R. Fan, Int. J. Nanoscience, 2002, 1, 1, which are fully incorporated herein by reference.

In various implementations, several factors are implemented in connection with the synthesis of Ge nanowires via the VLS mechanism for a low temperature CVD process. As shown in the conventional Au—Ge binary phase diagram (FIG. 3c), over a range of temperatures above ˜360° C. (the eutectic temperature), the VLS type of process takes place by increasing the concentration of Ge in Au. When varying the growth temperatures, it has been discovered that Ge nanowires can be synthesized at up to about 600° C. Using one or more of the approaches discussed herein, for example, involving nanowire growth from a nanocluster of gold, growth is achieved at a lower limit of temperature of about 275° C., which is lower than the eutectic temperature by about 80° C. In connection with this approach and example embodiment, it has been discovered that the melting temperature of a Ge—Au alloy is significantly suppressed for growth using Au nanoparticles from macroscopic Au for which the conventional phase diagram is derived. The 80° C. suppression of melting temperature for Ge—Au cluster can be implemented for Ge nanowire growth temperatures below 300° C.

According to other example embodiments, and referring to the Au—Ge phase diagram, growth of Ge nanowires seeded by Au nanoclusters is implemented at a variety of different low temperatures via the VLS process. In one implementation, Ge feedstock (e.g., germanium-containing gas) that can provide sufficient Ge species at selected temperatures are used, with the type and flow of feedstock being selected for the particular applications. In one implementation, desired nanowire growth results are obtained by controlling the GeH₄ decomposition through H₂ addition. In various embodiments, Germane can undergoes thermal decomposition via,

GeH₄.GeH₂+H₂ (1);

and

GeH₂.Ge+H₂ (2);

with activation energies of about 50 kcal/mol and less than about 35 kcal/mol for (1) and (2) respectively.

When varying the H₂ co-flow during CVD under a constant GeH₄ flow (20 sccm, 10% in He) at 275° C., it has been discovered that excessive GeH₄ pyrolysis exists for a H₂ flow rate below about 400 sccm, signaled by significant amorphous coating on the substrate and reactor wall. In addition, for H₂ flow rates greater than about 700 sccm, the substrate and CVD were clean and free of appreciable amorphous deposits, but results in little or no germanium nanowire growth. In connection with this example embodiment, it has been discovered that the increase of H₂ concentration suppresses GeH₄ decomposition (as H₂ is a product in reactions 1 and 2 above), leading to insufficient Ge feedstock for nanowire growth. In this regard, it has been discovered that active nanowire growth is achieved with a co-flow of about 500 sccm of H₂. Using this approach, the GeH₄ decomposition is well balanced to supply sufficient Ge feedstock and avoid excessive pyrolytic Ge deposition.

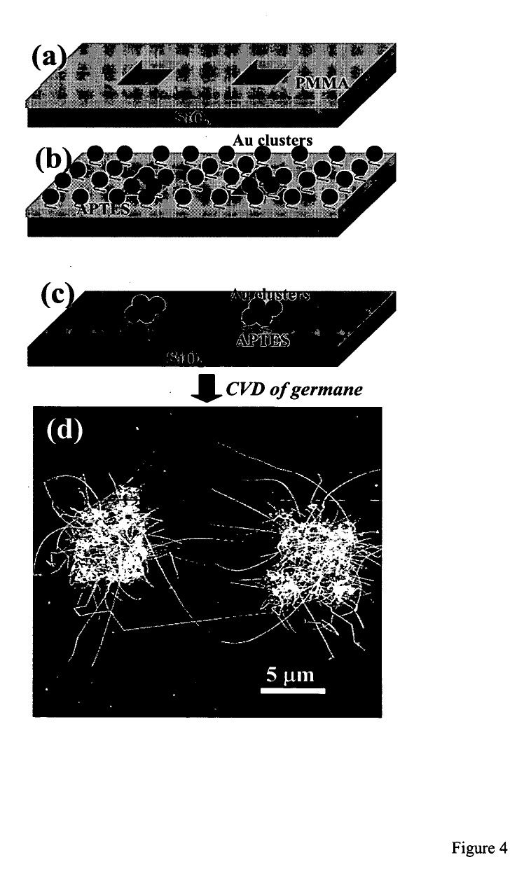

The synthesis of high purity and quality Ge nanowires using low temperature CVD approaches as discussed herein is implemented in a variety of applications. For example, FIGS. 4a-4d show the patterned growth of Ge nanowires. Au nanoparticles are patterned in arrays of micro-sized squares on SiO₂/Si substrates and followed by CVD growth using the nanoparticles (see the experimental section below for more information related to this example embodiment). SEM can be used to show that Ge nanowires are readily grown from the squares, as shown in FIG. 4d. The rest of the substrate remains generally clean with negligible particulate deposits. Nanowires emanating from well-defined locations on substrates have been found particularly useful, for example, for integration with electrical characterizations and devices.

In another example embodiment of the present invention, a soft synthesis condition is used for manufacturing nanowires. For instance, a 275° C.-synthesis temperature is implemented for the growth of high quality nanowires on a variety of substrates, including organic materials and materials such as glass.

### Experimental Data

The following example experimental embodiments and embodiments discussed in connection with the figures may be implemented in connection with one or more example embodiments of the present invention, including those discussed hereinabove.

Substrate Preparation and CVD Growth.

A Silicon (Si) substrate with 500 nm thermally grown oxide layer was cleaned by acetone, methanol and isopropanol. It was then dipped into a solution of 3-aminopropyltriethoxysilane (APTES) (12 μL in 20 mL H2O) for 30 minutes, rinsed with deionized water and blow-dried. The substrate was soaked in an aqueous Au colloid solution (20 nm in diameter, Alfa Aesar) for 1 h. The APTES monolayer renders the SiO₂ surface positively charged and allows for the deposition of Au colloids (negative charged) with high efficiency. AFM was carried out with a Digital Instrument Nanoscope III operated in the tapping mode. For CVD, the substrate was placed at the center of a 1 in quartz tube reactor in a furnace. The reactor was heated to 275° C. under 500 sccm of H₂ flow. The gas flow was then switched to 20 sccm of GeH₄ (10% in He, Voltaix, N.J.) and 500 sccm of H₂ (99.99%, Praxair, Calif.) for 15 min before switching the gas back to H₂ and cooling the system to room temperature.

Electron Microscopy.

After CVD growth, the substrate was characterized by a field emission SEM (Hitachi S-800) operated at an accelerating voltage of 25 kV. For TEM, Ge nanowire growth was carried out directly on TEM grids. Ni grids supporting ˜10 nm thick SiO₂ films (Ted Pella) were treated by APTES in the same manner as the SiO₂/Si substrates followed by Au particle deposition. The grids were imaged by TEM (Philips CM20, operating voltage 200 keV) before CVD to characterize the Au particles, and after CVD to characterize nanowires and particle-wire relationship.

Patterned Growth.

Polymethylmethacrylate (PMMA) was first patterned by electron beam lithography (or photolithography) on a SiO₂/Si substrate to form 5×5 μm wells (FIG. 4a). The substrate was treated with APTES and soaked in a Au colloid solution for Au particle deposition into the wells (FIG. 4b). Lift-off of the PMMA in acetone affords Au particles confined in square islands (FIG. 4c). The substrate was then subjected to CVD growth.

The various embodiments described above are provided by way of illustration only and should not be construed to limit the invention. Based on the above discussion and illustrations, those skilled in the art will readily recognize that various modifications and changes may be made to the present invention without strictly following the exemplary embodiments and applications illustrated and described herein. Such changes may include using other patterning techniques and growth conditions. For instance, the growth temperatures and gas flow rates can be varied, and the arrangements and implementations of the nanowires can be altered. Such modifications and changes do not depart from the true spirit and scope of the present invention.

What is claimed is:

1. A method for manufacturing a nanowire, the method comprising:
forming a conductive metal particle on an insulating substrate; and
introducing a germanium-containing gas to the conductive metal particle and growing a germanium nanowire extending from the conductive metal particle.

2. The method of claim 1, further comprising:
heating the insulating substrate, prior to introducing a germanium-containing gas.

3. The method of claim 1, further comprising introducing a co-flow of gas including hydrogen to the conductive metal particle while growing the germanium nanowire.

4. The method of claim 1, wherein forming a conductive metal particle includes forming at least one of: gold, a highly-conductive metal particle and a conductive metal particle having a eutectic phase in alignment with germanium.

5. A method of manufacturing a germanium nanowire, the method comprising:
patterning at least one region having gold on an insulating substrate;
placing the insulating substrate into a CVD chamber and heating the substrate; and
introducing a germanium-containing gas and hydrogen to the heated substrate and growing at least one germanium nanowire extending from the at least one patterned gold region.

6. The method of claim 5, wherein patterning at least one region having gold on an insulating substrate includes patterning at least one gold cluster.

7. The method of claim 5, wherein patterning at least one region having gold on an insulating substrate includes patterning at least one island of gold particles.

8. The method of claim 7, wherein patterning at least one island of gold particles includes patterning an island having a diameter of about 20 nanometers.

9. The method of claim 5, wherein placing the insulating substrate in a CVD chamber and heating the substrate includes sufficiently heating the substrate to cause the germanium-containing gas to dissolve in the patterned gold.

10. The method of claim 9, wherein sufficiently heating the substrate includes heating the substrate to about 250 degrees Celsius.

11. The method of claim 9, wherein sufficiently heating the substrate includes heating the substrate to at least about 275 degrees Celsius.

12. The method of claim 9, wherein sufficiently heating the substrate includes heating the substrate to about the eutectic temperature of an alloy formed including the germanium and gold.

13. The method of claim 12, wherein sufficiently heating the substrate includes heating the substrate to about 360 degrees Celsius.

14. The method of claim 9, wherein sufficiently heating the substrate includes heating the substrate to less than about 600 degrees Celsius.

15. The method of claim 9, wherein patterning at least one region having gold includes patterning the region sufficiently small such that the melting temperature of an alloy including the gold and germanium is below the eutectic temperature of about 360 degrees Celsius.

16. The method of claim 15, wherein sufficiently heating the substrate includes heating the substrate to between about 275 degrees Celsius and 300 degrees Celsius.

17. The method of claim 5, wherein introducing hydrogen to the heated substrate includes introducing a sufficient amount of hydrogen and inhibiting decomposition of the germanium-containing gas.

18. The method of claim 5, wherein growing at least one germanium nanowire includes forming an alloy including germanium and gold and precipitating a germanium nanowire from the alloy.

19. The method of claim 5, wherein growing at least one germanium nanowire extending from the at least one patterned gold region includes growing the nanowire extending to the substrate and lifting off the gold particle from the substrate via the nanowire growth.

20. The method of claim 5, wherein growing at least one germanium nanowire includes using a seeded vapor-liquid-solid mechanism via the gold.

21. A germanium nanowire manufactured in a manner not inconsistent with claim 5.

22. An electronic circuit comprising the germanium nanowire of claim 21.

23. A method for manufacturing a germanium-containing nanowire, the method comprising:
dissolving germanium in a gold particle and forming an alloy including germanium and gold;
introducing germanium to the alloy, increasing the concentration of germanium in the alloy and liquefying the alloy; and
after liquefying the alloy, further introducing germanium to the alloy and supersaturating the alloy with germanium; and
precipitating the supersaturated alloy and growing a germanium-containing nanowire.

24. An electronic circuit comprising:
a germanium nanowire manufactured in a manner not inconsistent with claim 23.

25. An arrangement for growing a germanium nanowire from an insulating substrate having a patterned gold region thereon, the arrangement comprising:
means for heating the substrate; and
means for introducing a germanium-containing gas to the heated substrate and growing at least one germanium nanowire extending from the patterned gold region.

26. A method for manufacturing a nanowire, the method comprising:
forming a conductive metal particle on an insulating substrate; and
introducing a gas including semiconducting material to the conductive metal particle and forming an alloy including the semiconducting material and the conductive metal particle and growing a nanowire extending from the alloy, the nanowire including said semiconducting material.
